(19) United States
(12) Patent Application Publication
(10) Pub. No.: US 2024/0402620 A1
(43) Pub. Date: Dec. 5, 2024

(54) SOURCE SELECTION MODULE AND ASSOCIATED METROLOGY AND LITHOGRAPHIC APPARATUSES

(71) Applicant: ASML NETHERLANDS B.V., Veldhoven (NL)

(72) Inventors: Paul Corné Henri DE WIT, Eindhoven (NL); Ronald Franciscus Herman HUGERS, Best (NL); Johannes Jacobus Matheus BASELMANS, Oirschot (NL)

(73) Assignee: ASML NETHERLANDS B.V., Veldhoven (NL)

(21) Appl. No.: 18/691,002

(22) PCT Filed: Aug. 29, 2022
(86) PCT No.: PCT/EP2022/073972

§ 371 Date: Mar. 11, 2024

(30) Foreign Application Priority Data
Sep. 22, 2021 (EP) 21198171.7

(51) Int. Cl. G03F 7/00

(52) U.S. Cl. CPC G03F 7/706849; G03F 7/706837; G03F 7/706845

(57) ABSTRACT

A source selection module for spectrally shaping a broadband illumination beam to obtain a spectrally shaped illumination beam. The source selection module includes a beam dispersing element for dispersing the broadband illumination beam; a grating light valve module for spatially modulating the broadband illumination beam subsequent to being dispersed; and a beam combining element to recombine the spatially modulated broadband illumination beam to obtain an output source beam.

### CROSS-REFERENCE TO RELATED APPLICATIONS

This application claims priority of EP Patent Application Number 21198171.7, which was filed on Sep. 22, 2021, and which is incorporated herein in its entirety by reference.

### FIELD OF THE INVENTION

The present invention relates to methods and apparatus usable, for example, in the manufacture of devices by lithographic techniques, and to methods of manufacturing devices using lithographic techniques. The invention relates more particularly to metrology sensors and lithography apparatuses having such a metrology sensor, and more particularly still to illumination arrangements for such metrology sensors.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

In some metrology applications, such as in some scatterometers or alignment sensors, imperfections in metrology targets can result in a wavelength/polarization dependent variation in a measured value from that target. As such, correction and/or mitigation for this variation is sometimes effected by performing the same measurement using multiple different wavelengths and/or polarizations (or more generally, multiple different illumination conditions). It would be desirable to improve switching and selection of the spectral components of illumination for such metrology applications.

### SUMMARY OF THE INVENTION

The invention in a first aspect provides a source selection module for spectrally shaping a broadband illumination beam to obtain a spectrally shaped illumination beam, comprising: a beam dispersing element for dispersing the broadband illumination beam; a grating light valve module for spatially modulating the broadband illumination beam subsequent to being dispersed; and a beam combining element to recombine the spatially modulated broadband illumination beam to obtain an output source beam.

Also disclosed is a metrology apparatus and a lithographic apparatus comprising a metrology device being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a schematic illustration of an alignment sensor adaptable according to an embodiment of the invention;

FIG. 4 comprises (a) a schematic diagram of a dark field scatterometer for use in measuring targets using a first pair of illumination apertures, (b) a detail of diffraction spectrum of a target grating for a given direction of illumination;

FIG. 5 is a schematic illustration of a grating light valve, illustrating its basic operation in (a) a top view, (b) an end-on view in a first configuration and (c) an end-on view in a second configuration;

FIG. 6 is a schematic illustration of an illumination arrangement comprising a grating light valve according to a first embodiment of the invention;

FIG. 7 is a schematic illustration of an illumination arrangement comprising a grating light valve according to a second embodiment of the invention;

FIG. 8 is a schematic illustration of the operating principal of an illumination arrangement as illustrated in FIG. 6, showing (a) an input spectrum, (b) a top view of radiation incident on the grating light valve, (c) an end-on view of radiation incident on the grating light valve and (d) the resultant output spectrum; and

FIG. 9 is a schematic illustration of an illumination arrangement comprising a grating light valve according to a second embodiment of the invention.

### DETAILED DESCRIPTION OF EMBODIMENTS

Before describing embodiments of the invention in detail, it is instructive to present an example environment in which embodiments of the present invention may be implemented.

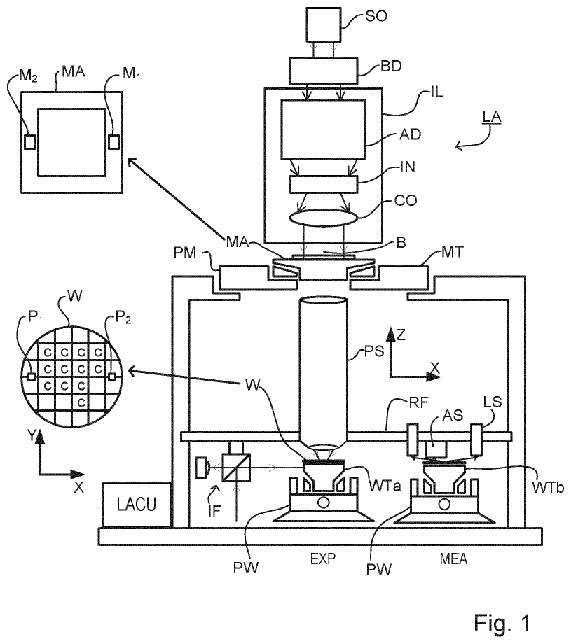

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

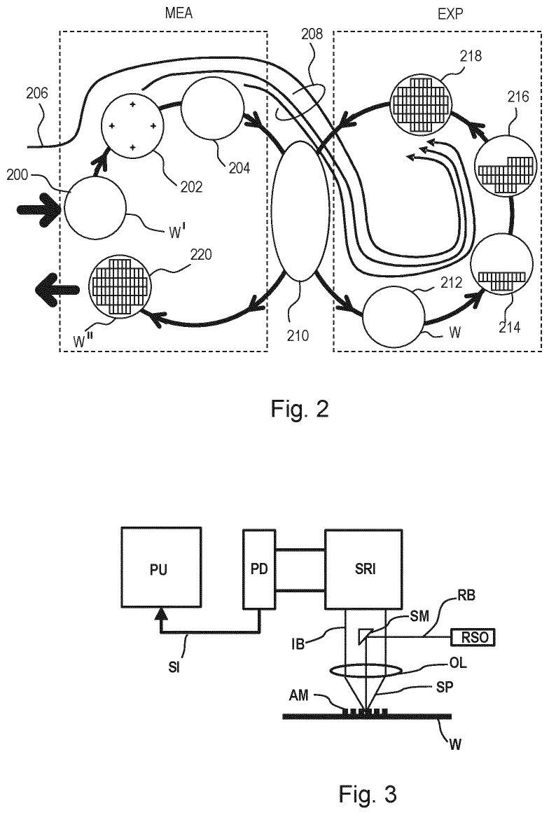

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTh (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W” is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers (by the same apparatus or a different lithographic apparatus). For this purpose, the substrate is provided with one or more sets of marks. Each mark is a structure whose position can be measured at a later time using a position sensor, typically an optical position sensor. The position sensor may be referred to as “alignment sensor” and marks may be referred to as “alignment marks”.

A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

A mark, or alignment mark, may comprise a series of bars formed on or in a layer provided on the substrate or formed (directly) in the substrate. The bars may be regularly spaced and act as grating lines so that the mark can be regarded as a diffraction grating with a well-known spatial period (pitch). Depending on the orientation of these grating lines, a mark may be designed to allow measurement of a position along the X axis, or along the Y axis (which is oriented substantially perpendicular to the X axis). A mark comprising bars that are arranged at +45 degrees and/or −45 degrees with respect to both the X- and Y-axes allows for a combined X- and Y-measurement using techniques as described in US2009/195768A, which is incorporated by reference.

The alignment sensor scans each mark optically with a spot of radiation to obtain a periodically varying signal, such as a sine wave. The phase of this signal is analyzed, to determine the position of the mark and, hence, of the substrate relative to the alignment sensor, which, in turn, is fixated relative to a reference frame of a lithographic apparatus. So-called coarse and fine marks may be provided, related to different (coarse and fine) mark dimensions, so that the alignment sensor can distinguish between different cycles of the periodic signal, as well as the exact position (phase) within a cycle. Marks of different pitches may also be used for this purpose.

Measuring the position of the marks may also provide information on a deformation of the substrate on which the marks are provided, for example in the form of a wafer grid. Deformation of the substrate may occur by, for example, electrostatic clamping of the substrate to the substrate table and/or heating of the substrate when the substrate is exposed to radiation.

FIG. 3 is a schematic block diagram of an embodiment of a known alignment sensor AS. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the mark AM is collimated (in this example via the objective lens OL) into an information-carrying beam IB. The term “diffracted” is intended to include zero-order diffraction from the mark (which may be referred to as reflection). A self-referencing interferometer SRI, e.g. of the type disclosed in U.S. Pat. No. 6,961,116 mentioned above, interferes the beam IB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

Intensity signals SI are supplied to a processing unit PU. By a combination of optical processing in the block SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels are repeated at different wavelengths for increased accuracy and/or for robust detection of the mark irrespective of the materials from which the mark is made, and materials on and/or below which the mark is provided. Improvements in performing and processing such multiple wavelength measurements are disclosed below.

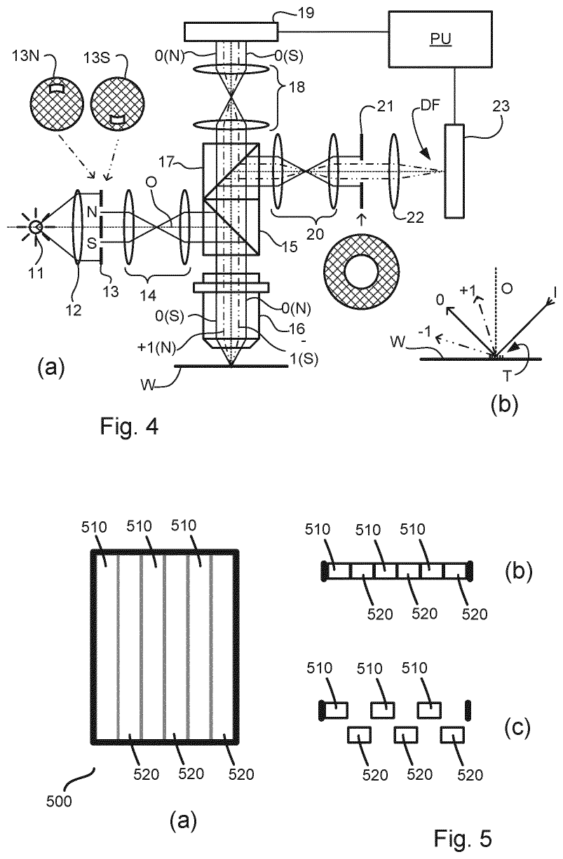

A metrology apparatus is shown in FIG. 4(a). A target T and diffracted rays of measurement radiation used to illuminate the target are illustrated in more detail in FIG. 4(b). The metrology apparatus illustrated is of a type known as a dark field metrology apparatus. The metrology apparatus depicted here is purely exemplary, to provide an explanation of dark field metrology. The metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source λ1 (e.g., a xenon lamp) is directed onto substrate W via a beam splitter 15 by an optical system comprising lenses 12, 14 and objective lens 16. These lenses are arranged in a double sequence of a 4F arrangement. A different lens arrangement can be used, provided that it still provides a substrate image onto a detector, and simultaneously allows for access of an intermediate pupil-plane for spatial-frequency filtering. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 13 of suitable form between lenses 12 and 14, in a plane which is a back-projected image of the objective lens pupil plane. In the example illustrated, aperture plate 13 has different forms, labeled 13N and 13S, allowing different illumination modes to be selected. The illumination system in the present examples forms an off-axis illumination mode. In the first illumination mode, aperture plate 13N provides off-axis from a direction designated, for the sake of description only, as ‘north’. In a second illumination mode, aperture plate 13S is used to provide similar illumination, but from an opposite direction, labeled ‘south’. Other modes of illumination are possible by using different apertures. The rest of the pupil plane is desirably dark as any unnecessary light outside the desired illumination mode will interfere with the desired measurement signals.

As shown in FIG. 4(b), target T is placed with substrate W normal to the optical axis O of objective lens 16. The substrate W may be supported by a support (not shown). A ray of measurement radiation I impinging on target T from an angle off the axis O gives rise to a zeroth order ray (solid line 0) and two first order rays (dot-chain line +1 and double dot-chain line −1). It should be remembered that with an overfilled small target, these rays are just one of many parallel rays covering the area of the substrate including metrology target T and other features. Since the aperture in plate 13 has a finite width (necessary to admit a useful quantity of light, the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown. Note that the grating pitches of the targets and the illumination angles can be designed or adjusted so that the first order rays entering the objective lens are closely aligned with the central optical axis. The rays illustrated in FIGS. 4(a) and 3(b) are shown somewhat off axis, purely to enable them to be more easily distinguished in the diagram.

At least the 0 and +1 orders diffracted by the target T on substrate W are collected by objective lens 16 and directed back through beam splitter 15. Returning to FIG. 4(a), both the first and second illumination modes are illustrated, by designating diametrically opposite apertures labeled as north (N) and south (S). When the incident ray I of measurement radiation is from the north side of the optical axis, that is when the first illumination mode is applied using aperture plate 13N, the +1 diffracted rays, which are labeled +1(N), enter the objective lens 16. In contrast, when the second illumination mode is applied using aperture plate 13S the −1 diffracted rays (labeled 1(S)) are the ones which enter the lens 16.

A second beam splitter 17 divides the diffracted beams into two measurement branches. In a first measurement branch, optical system 18 forms a diffraction spectrum (pupil plane image) of the target on first sensor 19 (e.g. a CCD or CMOS sensor) using the zeroth and first order diffractive beams. Each diffraction order hits a different point on the sensor, so that image processing can compare and contrast orders. The pupil plane image captured by sensor 19 can be used for focusing the metrology apparatus and/or normalizing intensity measurements of the first order beam. The pupil plane image can also be used for many measurement purposes such as reconstruction.

In the second measurement branch, optical system 20, 22 forms an image of the target T on sensor 23 (e.g. a CCD or CMOS sensor). In the second measurement branch, an aperture stop 21 is provided in a plane that is conjugate to the pupil-plane. Aperture stop 21 functions to block the zeroth order diffracted beam so that the image of the target formed on sensor 23 is formed only from the −1 or +1 first order beam. The images captured by sensors 19 and 23 are output to processor PU which processes the image, the function of which will depend on the particular type of measurements being performed. Note that the term ‘image’ is used here in a broad sense. An image of the grating lines as such will not be formed, if only one of the −1 and +1 orders is present.

The particular forms of aperture plate 13 and field stop 21 shown in FIG. 4 are purely examples. In another embodiment of the invention, on-axis illumination of the targets is used and an aperture stop with an off-axis aperture is used to pass substantially only one first order of diffracted light to the sensor. In other examples, a two quadrant aperture may be used. This may enable simultaneous detection of plus and minus orders, as described in US2010201963A1, mentioned above. Embodiments with optical wedges (segmented prisms or other suitable elements) in the detection branch can be used to separate the orders for imaging spatially in a single image, as described in US2011102753A1, mentioned above. In yet other embodiments, 2nd, 3rd and higher order beams (not shown in FIG. 4) can be used in measurements, instead of or in addition to the first order beams. In yet other embodiments, a segmented prism can be used in place of aperture stop 21, enabling both +1 and −1 orders to be captured simultaneously at spatially separate locations on image sensor 23.

In order to make the measurement radiation adaptable to these different types of measurement, the aperture plate 13 may comprise a number of aperture patterns formed around a disc, which rotates to bring a desired pattern into place. Note that aperture plate 13N or 13S can only be used to measure gratings oriented in one direction (X or Y depending on the set-up). For measurement of an orthogonal grating, rotation of the target through 90° and 270° might be implemented.

A light source for metrology applications usable for concepts disclosed herein may be based on a hollow core fiber such as a hollow core photonic crystal fiber (HC-PCF). The hollow core of the fiber may be filled with a gas acting as a broadening medium for broadening input radiation. Such a fiber and gas arrangement may be used to create a supercontinuum radiation source. Radiation input to the fiber may be electromagnetic radiation, for example radiation in one or more of the infrared, visible, UV, and extreme UV spectra. The output radiation may consist of or comprise broadband radiation, which may be referred to herein as white light. This is only one example of a broadband light source technology usable in methods and apparatuses disclosed herein, and other suitable technologies may instead be employed.

Metrology sensors include those designed predominately for pre-exposure metrology or alignment, such as the alignment sensor illustrated in FIG. 3, and those designed predominately for post-exposure metrology (e.g., overlay, CD and/or focus monitoring) such as the metrology apparatus illustrated in FIG. 4. In either case, it is often desirable to control the illumination spectrum, e.g., to switch the illumination between different wavelengths (colors) and/or wavefront profiles. More specifically, control of the illumination spectrum may comprise control of one or more of the following aspects of the illumination spectrum:
Tunable central frequency of a color band;
Tunable transmission of a color band;
Tunable bandwidth of a color band;
Switching of multiple color bands simultaneously on/off.

A number of methods are presently used for controlling the illumination spectrum. One such method comprises using an AOTF (acousto-optical tunable filter). However, using an AOTF has a number of disadvantages which include:
Out-of-band suppression is insufficient for some applications;
Limited flexibility in bandwidth control;
There is crosstalk between color bands if they are spaced close to each other.

One known method for spectral shaping comprises using spatial light modulation devices such as digital micromirror devices (DMDs). Arrangements using such devices are known which provide tunable central frequency and bandwidth of color bands and simultaneous switching of multiple bands. However, none of these devices are able to do all of this and also provide tunable transmission per color band.

Another method, which finds application for example in the apparatus of FIG. 4, comprises using color wheels which rotate different color filters into the beam path as required. However, the switching speed of such color wheels are slower than desired and they offer little or no flexibility in any of the aspects of control of the illumination spectrum listed above.

A source selection module is proposed which uses grating light valve (GLV) technology such as marketed by Silicon Light Machines (SLM). A GLV is a Micro-Electro-Mechanical Systems (MEMS) technology. FIG. 5 illustrates the principal. FIG. 5 is a schematic illustration of a GLV pixel or component 500 from (a) above and (b), (c) end-on. The GLV component comprises alternating GLV reflective ribbons of two types: static or bias ribbons 510 which are typically grounded along with a common electrode and driven or active ribbons 520 which are driven by an electronic driver channel. A GLV module may comprise any number of these GLV components 500 arranged in an array. The active and bias ribbons may be essentially identical other than in how they are driven. When no voltage is applied to the active ribbons 520, they are co-planar with the bias ribbons, a configuration illustrated in FIG. 5(b). In this configuration, the GLV acts essentially as a mirror, with incident light being specularly reflected. When a voltage is applied to the active ribbons 520, as illustrated in FIG. 5(c), they deflect relative to the bias ribbons 510, establishing a square-well diffraction grating. In this state, incident light is diffracted into fixed diffraction angles. The ratio of light reflected with respect to light diffracted can be continuously varied by controlling the voltage on the active ribbons 520, which controls the magnitude of their deflection. As such, the amount of light diffracted by the GLV can be controlled in an analog fashion from zero (full specular reflection) to all incident light (zero specular reflection).

It is proposed that a GLV module is used to provide tunable transmission per color band and therefore allow for better spectrum shaping and control. The GLV module may be used in a zeroth order mode such that the diffracted radiation is blocked/dumped and the zeroth order radiation is provided to the metrology tool. This has the advantage of preserving etendue.

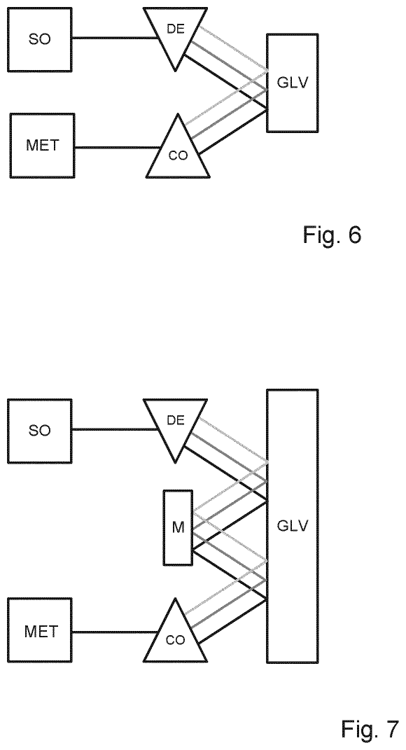

FIG. 6 is a schematic illustration of a source selection module according to a basic embodiment. A broadband or multiple color radiation source SO provides broadband or multiple color radiation. A dispersion element DE (which may be any suitable beam dispersion element e.g., a prism or grating) is used to disperse the broadband radiation. A grating light valve module GLV is used to modulate the spectrum of the dispersed radiation. The modulated radiation is then recombined using beam combiner CO (which may be any suitable beam combining element e.g., a prism or grating). The combined beam can then be used by a metrology tool MET as source illumination.

FIG. 7 is a schematic illustration of a refinement of the embodiment of FIG. 6, where the dispersed beam is double-passed (or passed multiple times) onto the GLV module. The arrangement is otherwise similar to that of FIG. 6. The dispersed beam is after a first modulation by the GLV module is reflected by a mirror M back to the GLV module where it is modulated a second time. An advantage of double-passing the dispersed beam onto the GLV is that the ratio between transmitted and blocked radiation is improved.

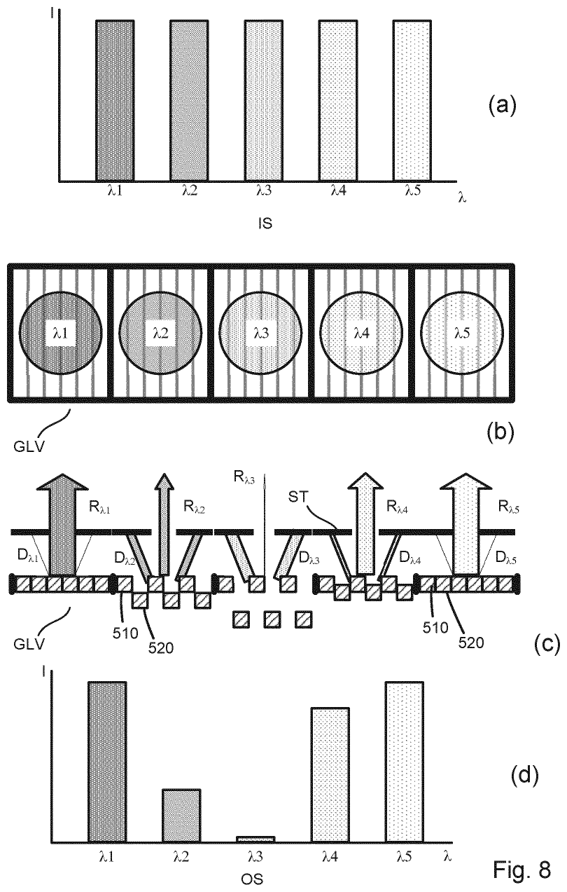

FIG. 8 is a schematic illustration which explains conceptually how the arrangement of FIG. 6 works. FIG. 8(a) is a plot of intensity λ against wavelength a showing an exemplary input spectrum IP describing the dispersed broadband radiation from the broadband radiation source SO. In this example, the broadband radiation comprises five color bands λ1 to λ5 of equal intensity. Of course, this is only an illustrative example and there may be more or fewer color bands in the input spectrum, the input spectrum may be continuous across a wavelength range and/or there may be some intensity variation between colors. Similarly, the GLV module may be operable to selectively attenuate more or fewer wavelength bands than the five shown here.

FIG. 8(b) shows each of these color bands on a respective portion of GLV module (shown looking down on the GLV ribbons). The illustrative drawing shows a color band per GLV component, although each color band may be incident on respective multiple GLV components (i.e., a plurality of GLV components are used to control each color). The plane defined by the GLV surface (e.g., the plane defined by the static ribbons) comprises a spectrally dispersed image plane of the system.

FIG. 8(c) conceptually illustrates how the GLV is used to modulate the input spectrum IS. In the specific example shown, the GLV module portions on which colors λ1 and λ5 are incident are fully reflective (i.e., there is no voltage applied to, and therefore no displacement of, the active ribbons 520 such that they are coplanar with the static ribbons 510). The width of arrows R_{λ1}, R_{λ5} represent the amount of light of colors λ1, λ5 which is reflected. The dotted lines D_{λ1}, R_{λ5} represent the negligible or zero light diffracted into higher (non-zero) diffraction orders by the GLV. For colors λ2, λ3, λ4, the active ribbons 520 are displaced by different amounts with respect to static ribbons 510 forming diffraction grating with respective different diffraction efficiencies. Once again the width of arrows R_{λ2}, R_{λ3}, R_{λ4} represent the amount of light of colors λ2, λ3 and λ4 which is reflected and the size of blocks labeled D_{λ2}, D_{λ3}, D_{λ4} represent the amount of light of colors λ2, λ3 and λ4 which his diffracted into higher (non-zero) diffraction orders by the GLV. All the diffracted light D_{λ2}, D_{λ3}, D_{λ4} (and D_{λ1}, D_{λ5} if not entirely zero) is blocked by a stop ST or higher order block, such that only reflected radiation Rj, R_{λ2}, R_{λ3}, R_{λ4} R_{λ5} is transmitted to the metrology device.

The stop ST may be located in a pupil plane of the system. The GLV module induces dispersion for all orders other than the zeroth order, leaving the zeroth order unaffected (the zeroth order etendue is not increased for example). This higher order dispersion results in a different beam position at the stop ST, allowing it to be blocked. Since the zeroth order is unaffected, the output beam will remain a (close to) Gaussian/single mode beam. This is particularly desirable for alignment applications (i.e., use in alignment sensors) as such alignment applications typically require a Gaussian or single mode beam.

FIG. 8(d) is a plot of intensity I against wavelength a showing the resultant output spectrum OP based on the configuration of the GLV module illustrated in FIG. 8(c). As can be seen, each spectral component λ1, λ2, λ3, λ4, λ5 has an intensity I corresponding to the GLV configuration of the respective portion of the GLV module for that color. In this way, the intensity of each spectral component can be varied continuously between a minimum and maximum transmission. The minimum transmission may be less than 10%, less than 5%, less than 3%, less than 2%, less than 1%, less than 0.5% or less than 0.1%, for example. The maximum transmission may be more than 90%, more than 95%, more than 97%, more than 98%, more than 99%, more than 99.5% or more than 99.9%, for example. In this way, it is possible to configure a specific spectral profile for any measurement, improving measurement accuracy.

Further improvements can be effected using the concepts disclosed herein. For example, the source lifetime may be extended using the source selection module disclosed herein. Some broadband sources, such as the hollow core fiber source described above, tend to lose intensity for only some spectral components over time rendering the source as a whole unusable. By using the GLV based source selection module, the output spectrum from the source can be monitored and one or more spectral components adjusted to compensate for intensity changes in any spectral component(s) over time. This makes it possible to increase the interval between source service actions such as replacement or repair of the source.

Another issue with some pulse-driven illumination sources such as the hollow core based source, is that pulse-to-pulse noise can be significant. It is proposed that the concepts disclosed herein can be used to mitigate this pulse-to-pulse noise. For example, the output spectrum (e.g., intensity per color and/or power spectral density PSD) can be measured (e.g., using a spectrometer, color filtered photodiode or other suitable device) and averaged or integrated over a suitable time period comprising a plurality of pulses. Based on the spectrum measurement, the GLV module can be adjusted on-the-fly (in real-time) to minimize intensity fluctuation, controlling the output spectrum in a real-time feedback loop. For example, a measurement (e.g., an alignment mark scan) can comprise a first measurement period or scan period (e.g., the first 50% to 90% of the full measurement period) where the GLV module is in a first configuration (e.g., in a normal configuration) and in parallel the output spectrum is measured. In a second measurement period or scan period (i.e., the remaining portion of the full measurement period), the GLV module can be controlled to correct the intensity of the desired spectral components (those to be used for that measurement, e.g., according to a measurement recipe). As such, if it is determined that there is too much blue (or other spectral component) light during the first measurement period, the GLV module can be controlled to reduce blue wavelengths during the second measurement period. This can significantly reduce the intensity variation.

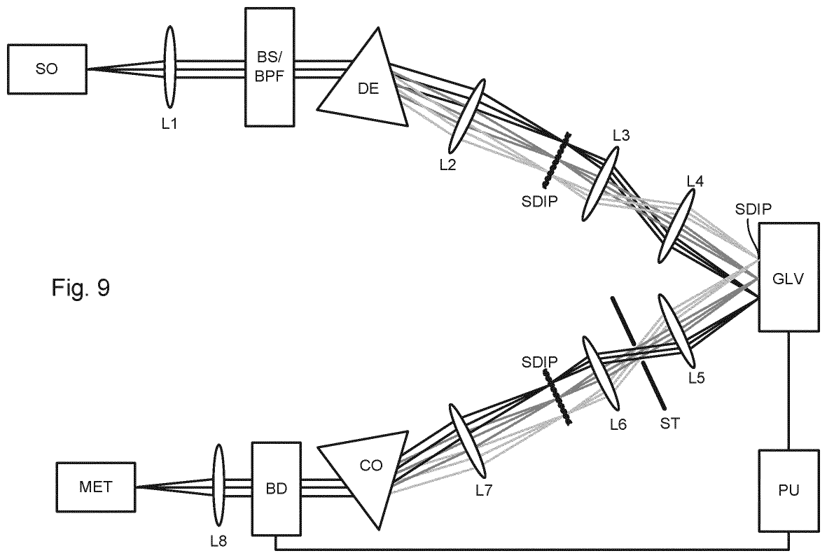

FIG. 9 is a schematic illustration in more detail than the illustration of FIGS. 6 and 7 and further incorporating elements for the optional improvements just described. A broadband source SO emits broadband radiation. A lens system represented by lenses L1 and L2 provide access to a pupil plane in which a beam steering and beam position feedback module BS/BPF is located. This can be used to control beam position in a feedback loop. Also in a pupil plane is a dispersion element DE (e.g., a grating or prism). Lenses L2 and L3 define a first spectrally dispersed image plane (or field plane), while lens L4 focuses the dispersed radiation on the GLV module GLV at a second spectrally dispersed image plane. The reflected (zeroth order) radiation from the GLV is captured by lens L5, with lenses L5 and L6 providing access to a pupil plane in which a stop ST is located. Stop ST blocks any diffraction orders (not shown) from the GLV module, while passing the zeroth order substantially unattenuated. Lenses L6 and L7 define a third spectrally dispersed image plane SDIP, while lenses L7 and L8 provide access to the pupil plane, in which beam combiner CO is located. Also located between lenses L7 and L8 may be a beam diagnostic module BD, which may be operable to measure the output spectrum (e.g., intensities per spectral component/PSD). A processing unit PU may control the GLV module, and further may be connected to the beam diagnostic module BD to effect a feedback control as has been described. Finally, lens L8 focuses the output beam into a metrology device MET (e.g., into a suitable optical fiber such as a single mode fiber to transport the radiation to the metrology device MET).

It can be appreciated that the dispersed illumination can be double passed (or multiply passed) onto the GLV module in the embodiment illustrated in FIG. 9, in the manner illustrated by FIG. 7.

In an embodiment, the source selection module (e.g., any of the source selection modules already described) may comprise a multiband-pass color filter element such as a fixed multiband-pass color filter element. Such a multiband-pass color filter element may be located at the output of the source selection module for example (e.g., between the beam combiner and metrology device in the FIGS. 6, 7 and 8). Such a filter can be used to define in a well-controlled manner, the number of color bands, their central wavelengths and their bandwidths, with the GLV module enabling control of transmission per color band. In this manner, the central wavelengths and bandwidths of the color bands are defined by a (very) well controlled fixed element in optical path, although there will be reduced flexibility compared to GLV-based source selection module without such a multiband filter element. In comparison to a conventional selection module which uses a fixed multiband-pass color filter only (without a GLV module), this embodiment provides the flexibility of selecting one or multiple bands and controlling the bands over time.

The embodiments may further be described using the following clauses:

1. A source selection module for spectrally shaping a broadband illumination beam to obtain a spectrally shaped illumination beam, comprising:
a beam dispersing element for dispersing the broadband illumination beam;
a grating light valve module for spatially modulating the broadband illumination beam subsequent to being dispersed; and
a beam combining element to recombine the spatially modulated broadband illumination beam to obtain an output source beam.
   2. A source selection module as in clause 1, wherein control of the grating light valve module controls transmission per spectral component of the spectrally shaped illumination beam.
   3. A source selection module as in clause 1 or 2, being configured such that specularly reflected radiation from said grating light valve module is comprised within said output source beam, and any radiation diffracted by said grating light valve module is not comprised within said output source beam.
   4. A source selection module as in clause 3, comprising a stop operable to block all said radiation diffracted by said grating light valve module and to transmit said specularly reflected radiation.
   5. A source selection module as in clause 4, wherein said stop is located in a pupil plane between said grating light valve module and said beam combining element.
   6. A source selection module as in any preceding clause, wherein the source selection module comprises at least one imaging optic operable to image the dispersed broadband illumination beam onto said grating light valve module.
   7. A source selection module as in any preceding clause, wherein said grating light valve module is configurable such that intensity of each spectral component of said dispersed broadband illumination beam is individually controllable.
   8. A source selection module as in clause 7, wherein said individual control of the intensity of each spectral component comprises a continuous analogue control between a minimum and maximum intensity.
   9. A source selection module as in any preceding clause, comprising a processing unit operable to control at least said grating light valve module.
   10. A source selection module as in clause 9, further comprising a beam diagnostic module operable to measure one or more parameters of an output spectrum of the output source beam.
   11. A source selection module as in clause 10, wherein said beam diagnostic module is operable to measure said output spectrum over a time period; and said processing unit is operable to adjust one or more spectral components of the dispersed broadband illumination beam via control of said grating light valve module to compensate for intensity changes in any one or more spectral components over said time period.
   12. A source selection module as in clause 10 or 11, wherein said beam diagnostic module is operable to measure said output spectrum over a first portion of a measurement period; and based on the measured output spectrum, said processing unit is operable to adjust one or more spectral components of the dispersed broadband illumination beam via control of said grating light valve module to minimize intensity fluctuation caused by source noise in a second portion of the measurement period.
   13. A source selection module as in clause 12, wherein said processing unit is operable to adjust said one or more spectral components in real time during a measurement.
   14. A source selection module as in clause 12 or 13, wherein said processing unit is operable to average a measured parameter of one or more spectral components over said first measurement period.
   15. A source selection module as in any of clauses λ1 to 14, wherein said measuring the output spectrum comprises measuring intensity per spectral component and/or power spectral density.
   16. A source selection module as in any of clauses 10 to 15, wherein said beam diagnostic module comprises a spectrometer or a color filtered photodiode.
   17. A source selection module as in any preceding clause, comprising a beam directing arrangement operable to pass said dispersed broadband illumination beam two or more times on said grating light valve module, wherein said dispersed broadband illumination beam is modulated on each pass.
   18. A source selection module as in any preceding clause, comprising an illumination source for providing said input illumination.
   19. A source selection module as in clause 18, wherein said illumination source comprises a low etendue illumination source.
   20. A source selection module as in clause 18 or 19, wherein said illumination source comprises a hollow core fiber for confining a broadening medium and an excitation radiation source operable to provide excitation radiation for exciting said broadening medium.
   21. A source selection module as in any preceding clause, comprising a multiband-pass color filter element operable to define one or more of: the number of spectral component bands comprised within the output source beam, the central wavelength of each spectral component band comprised within the output source beam and the bandwidth of each spectral component band comprised within the output source beam.
   22. A metrology device comprising the source selection module of any preceding clause to provide measurement illumination.
   23. A metrology device as in clause 22, wherein the metrology device comprises a scatterometer.
   24. A metrology device as in clause 23, comprising:
a support for a substrate;
an optical system for directing said measurement illumination to a structure on said substrate; and
a detector for detecting the measurement radiation scattered by the structure on the substrate.
   25. A metrology device as in clause 22, wherein the metrology device comprises an alignment sensor.
   26. A lithographic apparatus comprising:
a patterning device support for supporting a patterning device;
a substrate support for supporting a substrate; and the metrology device of clause 25 being operable to perform alignment of said patterning device and/or said substrate support.

In addition to the advantages already discussed, the source selection module disclosed herein can improve signal to noise ratio by increasing intensity of the desired spectral components. For example, a typical source presently may provide 12 colors simultaneously to the wafer. The intensity of each color must be maintained below a safety threshold such that the combined intensity of all 12 colors on the wafer does not damage the wafer. By using the source selection module disclosed herein, the intensity for the spectral components not being used can be minimized, which allows the intensity of the desired spectral components to be raised significantly. For example, where a safety threshold is 50 mW (purely as an example), in the present system each color (assuming 12 colors) can only have a maximum intensity of 4 mW. However, if only two of these colors are to be used for a measurement, the other colors can be attenuated to zero intensity (or close to this) and the two desired colors can be allowed to have an intensity up to 25 mW each (or a combined intensity of 50 mW distributed between the desired two (or more) colors in any ratio according to the needs of the measurement).

It should be appreciated that the term color is used throughout this text synonymously with wavelength or spectral component and the colors may include those outside the visible band (e.g., infrared or ultraviolet wavelengths).

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The breadth and scope of the present invention should not be limited by any of the above-described exemplary embodiments, but should be defined only in accordance with the following claims and their equivalents.

1. A source system for spectrally shaping a broadband illumination beam to obtain a spectrally shaped illumination beam, the system comprising:
a beam dispersing element configured to disperse the broadband illumination beam;
a grating light valve module configured to spatially modulate the broadband illumination beam subsequent to being dispersed; and
a beam combining element to recombine the spatially modulated broadband illumination beam to obtain an output source beam.

2. The system as claimed in claim 1, wherein control of the grating light valve module controls transmission per spectral component of the spectrally shaped illumination beam.

3. The system as claimed in claim 1, configured such that specularly reflected radiation from the grating light valve module is comprised within the output source beam, and any radiation diffracted by the grating light valve module is not comprised within the output source beam.

4. The system as claimed in claim 3, comprising a stop operable to block all the radiation diffracted by the grating light valve module and to transmit the specularly reflected radiation.

5. The system as claimed in claim 4, wherein the stop is located in a pupil plane between the grating light valve module and the beam combining element.

6. The system as claimed in claim 1, further comprising at least one imaging optic configured to image the dispersed broadband illumination beam onto the grating light valve module.

7. The system as claimed in claim 1, wherein the grating light valve module is configurable such that intensity of each spectral component of the dispersed broadband illumination beam is individually controllable.

8. The system as claimed in claim 7, wherein the individual control of the intensity of each spectral component comprises a continuous analogue control between a minimum and maximum intensity.

9. The system as claimed in claim 1, further comprising a processing unit configured to control at least the grating light valve module.

10. The system as claimed in claim 9, further comprising a beam diagnostic module configured to measure one or more parameters of an output spectrum of the output source beam.

11. The system as claimed in claim 10, wherein:
the beam diagnostic module is configured to measure the output spectrum over a time period; and
the processing unit is configured to adjust one or more spectral components of the dispersed broadband illumination beam via control of the grating light valve module to compensate for intensity changes in any one or more spectral components over the time period.

12. The system as claimed in claim 10, wherein:
the beam diagnostic module is configured to measure the output spectrum over a first portion of a measurement period; and
based on the measured output spectrum, the processing unit is configured to adjust one or more spectral components of the dispersed broadband illumination beam via control of the grating light valve module to minimize intensity fluctuation caused by source noise in a second portion of the measurement period.

13. The system as claimed in claim 12, wherein the processing unit is configured to adjust the one or more spectral components in real time during a measurement.

14. The system as claimed in claim 12, wherein the processing unit is configured to average a measured parameter of one or more spectral components over the first portion of the measurement period.

15. The system as claimed in claim 11, wherein the measurement of the output spectrum comprises measurement of intensity per spectral component and/or power spectral density.

16. The system as claimed in claim 10, wherein the said beam diagnostic module comprises a spectrometer or a color filtered photodiode.

17. The system as claimed in claim 1, further comprising a beam directing arrangement configured to pass the dispersed broadband illumination beam two or more times on the grating light valve module, wherein the dispersed broadband illumination beam is modulated on each pass.

18. The system as claimed in claim 1, further comprising an illumination source configured to provide the input illumination.

19. The system as claimed in claim 18, wherein the illumination source comprises a low etendue illumination source.

20. The system as claimed in claim 18, wherein the illumination source comprises a hollow core fiber configured to confine a broadening medium and an excitation radiation source configured to provide excitation radiation for exciting the broadening medium.
